(19) United States
(12) Patent Application Publication
(10) Pub. No.: US 2026/0198143 A1
(43) Pub. Date: Jul. 9, 2026

(54) LIGHT EMITTING DIODE, ARTICLE COMPRISING THE SAME, AND METHOD FOR PREPARING THE ARTICLE

(71) Applicant: BOE HC SEMITEK (ZHEJIANG) CO., LTD., Jinhua (CN)

(72) Inventors: Zhe RUI, Jinhua (CN); Bolin WEI, Jinhua (CN); Yanhong TIAN, Jinhua (CN); Junlei WU, Jinhua (CN); Liangxia LIU, Jinhua (CN); Lingfeng YIN, Jinhua (CN)

(21) Appl. No.: 19/553,490

(22) Filed: Mar. 2, 2026

Related U.S. Application Data
(63) Continuation-in-part of application No. PCT/CN2024/100752, filed on Jun. 21, 2024.

(30) Foreign Application Priority Data
Aug. 29, 2023 (CN) 202311101498.6

(51) Int. Cl. H10H 20/831; H10H 20/01; H10H 20/812; H10H 29/24

(52) U.S. Cl. CPC H10H 20/8312; H10H 20/032; H10H 20/812; H10H 29/24

(57) ABSTRACT

An LED including a substrate, a first light-emitting unit, a second light-emitting unit, an insulating layer, and a transparent conductive layer. The first and second light-emitting units are spaced apart and each includes a first semiconductor layer, a multiple quantum well layer, and a second semiconductor layer sequentially stacked. The second semiconductor layer has a recess for exposing the first semiconductor layer. The insulating layer covers the first and second light-emitting units and is disposed on the substrate surface. The insulating layer has first via holes respectively exposing the second semiconductor layers of the first and second light-emitting units, and second via holes respectively exposing the recesses of the first and second light-emitting units. The transparent conductive layer is disposed on the second semiconductor layers of the first and second light-emitting units and is electrically connected to the corresponding second semiconductor layers through the first via holes.

### CROSS-REFERENCE TO RELATED APPLICATION

This application is a continuation-in-part of International Patent Application No. PCT/CN2024/100752 with an international filing date of Jun. 21, 2024, designating the United States, now pending, further claims foreign priority benefits to Chinese Patent Application No. 202311101498.6 filed Aug. 29, 2023. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, MA 02142.

### BACKGROUND

The present disclosure relates to the field of optoelectronic manufacturing technology, and more particularly, to a light emitting diode, an article comprising the same, and a method for preparing the article.

A Light Emitting Diode (LED) is a common light-emitting device. LEDs are typically formed by fabricating various film layers on a substrate, performing patterning processes, and then dicing the substrate into individual LED chips.

### SUMMARY

Embodiments of the present disclosure provide an LED, an article comprising the same, and a method for preparing the article.

In one aspect, an embodiment of the present disclosure provides an article. The article comprises a substrate and a plurality of LED devices disposed on the substrate. Each LED device comprises an epitaxial layer, an insulating layer, and a transparent conductive layer sequentially disposed on the substrate. The insulating layer has a first via hole exposing the epitaxial layer, and the transparent conductive layer is connected to the epitaxial layer through the first via hole. The substrate has a central region and an annular region surrounding the central region. A plurality of the LED devices are arranged in both the central region and the annular region. An area of a contact surface between the first via hole and the epitaxial layer in the LED device in the central region is greater than an area of a contact surface between the first via hole and the epitaxial layer in the LED device in the annular region, and a thickness of the transparent conductive layer in the LED device in the central region is greater than a thickness of the transparent conductive layer in the LED device in the annular region.

In an embodiment of the disclosure, the substrate is a wafer, the central region is circular, the annular region is annular, and the central region and the annular region are concentrically distributed.

In an embodiment of the disclosure, a ratio of a radius of the central region to a radius of the substrate is 0.8 to 0.9, and a ratio of a width of the annular region to the radius of the substrate is 0.1 to 0.2.

In an embodiment of the disclosure, the annular region comprises a plurality of sub-annular regions sequentially surrounding the central region. For any two adjacent sub-annular regions among the plurality of sub-annular regions, a maximum width of the first via hole in the LED device in the sub-annular region proximal to the central region is greater than a maximum width of the first via hole in the LED device in the sub-annular region distal from the central region, and a thickness of the transparent conductive layer in the LED device in the sub-annular region proximal to the central region is greater than a thickness of the transparent conductive layer in the LED device in the sub-annular region distal from the central region.

In an embodiment of the disclosure, the annular region comprises a first sub-annular region, a second sub-annular region, and a third sub-annular region sequentially surrounding the central region. A ratio of a width of the first sub-annular region to the radius of the substrate is 0.05 to 0.15, a ratio of a width of the second sub-annular region to the radius of the substrate is 0.03 to 0.1, and a ratio of a width of the third sub-annular region to the radius of the substrate is 0.02 to 0.05.

In an embodiment of the disclosure, the first via holes of the LED devices have the same shape. A maximum width of the first via hole of the LED device in the first sub-annular region is 6 µm to 8 µm, a maximum width of the first via hole of the LED device in the second sub-annular region is 4 µm to 6 µm, and a maximum width of the first via hole of the LED device in the third sub-annular region is 3 µm to 5 µm.

In an embodiment of the disclosure, a maximum width of the first via hole of the LED device in the central region is 9 µm to 11 µm.

In an embodiment of the disclosure, the LED device comprises a first light-emitting unit, a second light-emitting unit, an insulating layer, and a transparent conductive layer. Each of the first light-emitting unit and the second light-emitting unit comprises a first semiconductor layer, a multiple quantum well layer, and a second semiconductor layer sequentially stacked. The second semiconductor layer defines a recess for exposing the first semiconductor layer. The insulating layer has a first via hole exposing the second semiconductor layer of the first light-emitting unit and the second semiconductor layer of the second light-emitting unit, and a second via hole exposing the recess of the first light-emitting unit and the recess of the second light-emitting unit. The transparent conductive layer is disposed on two second semiconductor layers and is connected to the two second semiconductor layers through two first via holes, respectively. The first semiconductor layer of the first light-emitting unit is electrically connected to the second semiconductor layer of the second light-emitting unit.

In an embodiment of the disclosure, the LED device further comprises a connection electrode, a first electrode, and a second electrode. The connection electrode is disposed on the insulating layer. A first portion of the connection electrode is connected to the first semiconductor layer of the first light-emitting unit through the second via hole, and a second portion of the connection electrode is connected to the transparent conductive layer of the second light-emitting unit. The first electrode is disposed on the transparent conductive layer of the first light-emitting unit. The second electrode is disposed in the recess of the second light-emitting unit and is connected to the first semiconductor layer through the second via hole.

In an embodiment of the disclosure, the transparent conductive layer comprises two conductive portions. Each conductive portion has a rectangular region and a protruding region connected thereto. The protruding region is disposed at a long side of the rectangular region. One of the two conductive portions is disposed on the second semiconductor layer of the first light-emitting unit, and the other of the two conductive portions is disposed on the second semiconductor layer of the second light-emitting unit. Each of the first light-emitting unit and the second light-emitting unit defines two recesses. The two recesses of the first light-emitting unit are disposed on two sides of the protruding region corresponding to the first light-emitting unit, and the two recesses of the second light-emitting unit are disposed on two sides of the protruding region corresponding to the second light-emitting unit.

In an embodiment of the disclosure, a center of the first via hole is positioned on a midline of the long side of the rectangular region and on a midline of a perpendicular line between a side of the protruding region away from the rectangular region and a long side of the rectangular region away from the protruding region.

In an embodiment of the disclosure, the first light-emitting unit has two first electrodes symmetrically distributed on the transparent conductive layer. The second light-emitting unit has two second electrodes respectively disposed in the two recesses of the second light-emitting unit and symmetrically arranged. The two first electrodes and the two second electrodes are symmetrically distributed.

In an embodiment of the disclosure, the light emitting diode comprises two connection electrodes symmetrically arranged.

In an embodiment of the disclosure, the insulating layer comprises an aluminum oxide layer and a silicon oxide layer sequentially stacked.

In another aspect, a preparation method of an article is provided. The preparation method comprises: providing a substrate having a central region and an annular region surrounding the central region; and forming a plurality of LED devices on the substrate. Each LED device comprises an epitaxial layer, an insulating layer, and a transparent conductive layer sequentially stacked on the substrate. The insulating layer has a first via hole exposing the epitaxial layer, and the transparent conductive layer is connected to the epitaxial layer through the first via hole. A plurality of the LED devices are arranged in both the central region and the annular region. An area of a contact surface between the first via hole and the epitaxial layer in the LED device in the central region is greater than an area of a contact surface between the first via hole and the epitaxial layer in the LED device in the annular region, and a thickness of the transparent conductive layer in the LED device in the central region is greater than a thickness of the transparent conductive layer in the LED device in the annular region.

In yet another aspect, an LED is provided. The LED comprises the LED device as described herein.

### BRIEF DESCRIPTION OF THE DRAWINGS

To illustrate the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of an article according to an embodiment of the present disclosure;

FIG. 2 is a schematic structural diagram of an LED according to an embodiment of the present disclosure;

FIG. 3 is a cross-sectional view taken along line A-A in FIG. 2;

FIG. 4 is a partial enlarged view of area M in FIG. 1;

FIG. 5 is a flowchart of a preparation method of an article according to an embodiment of the present disclosure.

Reference numerals in the drawings: 10: Substrate; 11: Central region; 12: Annular region; 121: First sub-annular region; 122: Second sub-annular region; 123: Third sub-annular region; 200: LED device; 210: Epitaxial layer; 211: First light-emitting unit; 212: Second light-emitting unit; 213: First semiconductor layer; 214: Multiple quantum well layer; 215: Second semiconductor layer; 220: Insulating layer; 221: First via hole; 222: Second via hole; 230: Transparent conductive layer; 230a: Conductive portion; 231: Rectangular region; 232: Protruding region; 30: Connection electrode; 31: First electrode; 32: Second electrode; 40: Passivation layer; 51: First bonding pad; 52: Second bonding pad.

### DETAILED DESCRIPTION

To make the objectives, technical solutions, and advantages of the present disclosure clearer, the following further describes the embodiments of the present disclosure in detail with reference to the accompanying drawings.

Unless otherwise defined, technical or scientific terms used herein shall have the ordinary meaning as understood by one of ordinary skill in the art to which this disclosure belongs. The terms "first," "second," "third," and the like used in the specification and claims of the present disclosure do not denote any order, quantity, or importance, but are merely used to distinguish different components. Similarly, terms such as "a" or "an" do not denote a limitation of quantity, but rather denote the presence of at least one. Terms such as "include," "comprise," and the like mean that elements or items appearing before these terms encompass elements or items listed after these terms and their equivalents, but do not preclude other elements or items. Terms such as "connected," "coupled," and the like are not limited to physical or mechanical connections, but may include electrical connections, whether direct or indirect. Terms such as "upper," "lower," "left," "right," "top," "bottom," and the like are used only to indicate relative positional relationships. When the absolute position of the described object changes, the relative positional relationships may change accordingly.

An LED typically includes a substrate, an epitaxial layer, a transparent conductive layer, and electrodes. The epitaxial layer includes a first semiconductor layer, a multiple quantum well layer, and a second semiconductor layer sequentially stacked on the substrate. The transparent conductive layer is located on the second semiconductor layer, and electrodes are located on the transparent conductive layer. The transparent conductive layer spreads current to various areas of the second semiconductor layer. The transparent conductive layer is typically fabricated using an evaporation apparatus.

Due to fluctuations in the evaporation apparatus, the thickness of the transparent conductive layer formed on different regions of the substrate may be uneven. Specifically, the thickness of the transparent conductive layer of the LED in the central region of the substrate is greater than the thickness of the transparent conductive layer of the LED in the edge region of the substrate. A thinner transparent conductive layer absorbs less light, resulting in higher brightness of the corresponding LED; conversely, a thicker transparent conductive layer absorbs more light, resulting in lower brightness of the corresponding LED. Therefore, uneven thickness of the transparent conductive layer across different regions of the substrate leads to poor brightness uniformity among LEDs on the substrate.

To address this, embodiments of the present disclosure provide an article for manufacturing LEDs, which can improve the brightness uniformity of multiple LEDs formed on the same substrate.

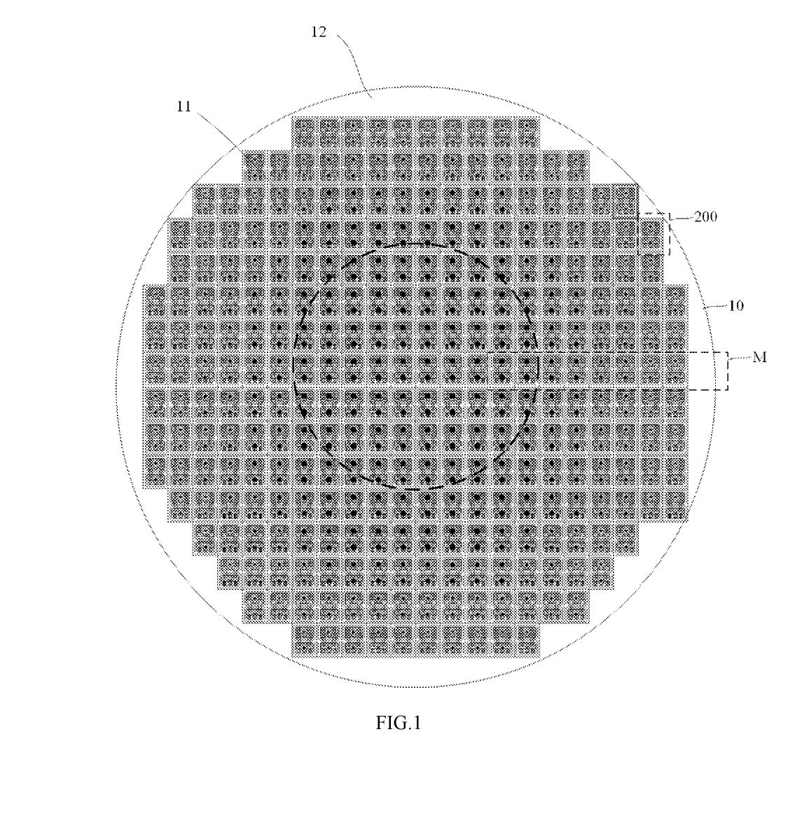

FIG. 1 is a schematic structural diagram of an article according to an embodiment of the present disclosure. As shown in FIG. 1, the article includes a substrate 10 and LED devices 200 located on the substrate 10. The substrate 10 has a central region 11 and an annular region 12. The annular region 12 surrounds the central region 11. A plurality of LED devices 200 are arranged in both the central region 11 and the annular region 12.

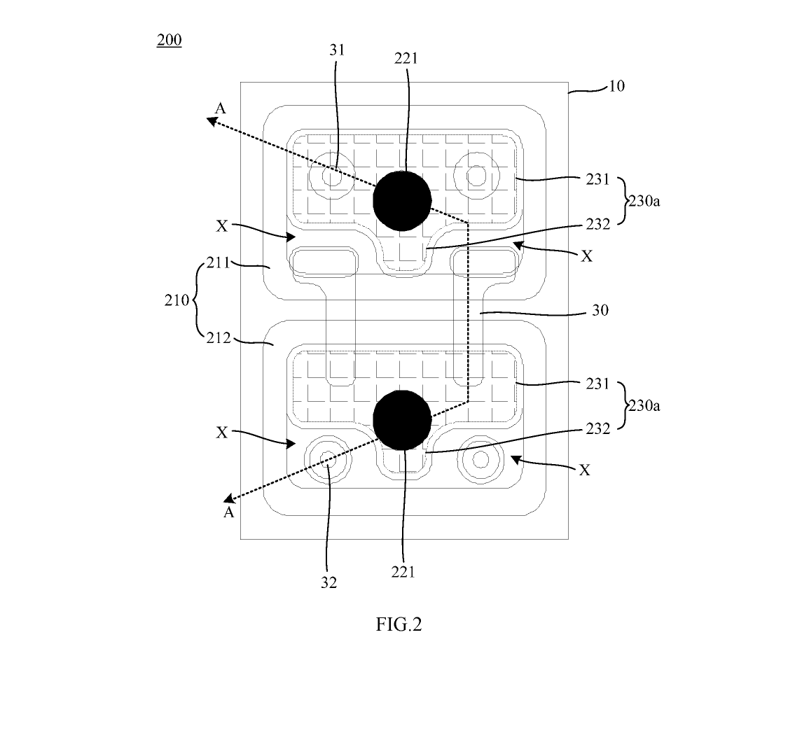

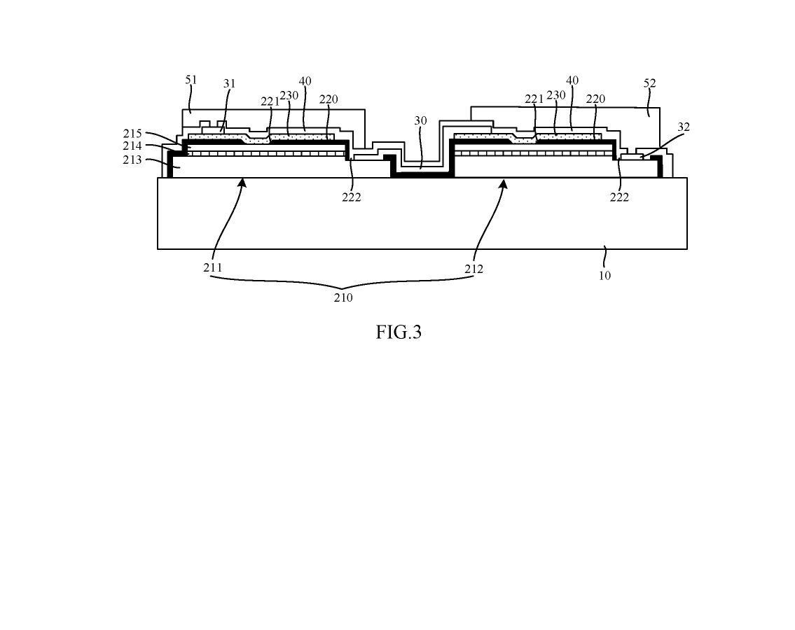

FIG. 2 is a schematic structural diagram of an LED according to an embodiment of the present disclosure. FIG. 3 is a cross-sectional view taken along line A-A in FIG. 2. As shown in FIGS. 2 and 3, each LED device 200 includes an epitaxial layer 210, an insulating layer 220, and a transparent conductive layer 230 sequentially stacked on the substrate 10. The insulating layer 220 has a first via hole 221 exposing the epitaxial layer 210, and the transparent conductive layer 230 is connected to the epitaxial layer 210 through the first via hole 221.

As shown in FIG. 1, a maximum width of the first via hole 221 in the LED device 200 in the central region 11 is greater than a maximum width of the first via hole 221 in the LED device 200 in the annular region 12, and a thickness of the transparent conductive layer 230 in the LED device 200 in the central region 11 is greater than a thickness of the transparent conductive layer 230 in the LED device 200 in the annular region 12.

In this embodiment, the maximum width of the first via hole refers to a distance between two farthest points on the contact surface between the first via hole and the epitaxial layer.

For example, when the first via hole is a circular hole, the maximum width of the first via hole is its diameter. Here, a circular hole refers to a hole whose cross-section parallel to the bearing surface of the substrate is circular.

For another example, when the first via hole is a rectangular hole, the maximum width of the first via hole is the length of its diagonal. Here, a rectangular hole refers to a hole whose cross-section parallel to the bearing surface of the substrate is rectangular.

The bearing surface of the substrate refers to the surface of the substrate on which the LED devices are located.

In this embodiment, the shapes of the first via holes 221 of the LED devices 200 are the same, for example, all are circular holes or all are rectangular holes. When the shapes of the first via holes 221 of the LED devices 200 are the same, the maximum width of the first via hole is positively correlated with the area of the contact surface between the first via hole and the epitaxial layer. A larger maximum width of the first via hole corresponds to a larger area of the contact surface; conversely, a smaller maximum width corresponds to a smaller area of the contact surface.

In other embodiments, among all LED devices 200, there may be cases where the first via holes 221 differ. For example, the first via holes 221 of the LED devices 200 in the central region 11 may be circular holes, while the first via holes 221 of the LED devices 200 in the annular region 12 may be rectangular holes. This embodiment imposes no limitation thereon, as long as it is ensured that the area of the contact surface between the first via hole 221 and the epitaxial layer in the LED device 200 in the central region 11 is greater than the area of the contact surface between the first via hole 221 and the epitaxial layer in the LED device 200 in the annular region 12.

The LED device 200 provided in this embodiment includes an epitaxial layer 210, an insulating layer 220, and a transparent conductive layer 230 sequentially stacked. The transparent conductive layer 230 is connected to the underlying epitaxial layer 210 through the first via hole 221 in the insulating layer 220. The light-emitting area of the LED device 200 is limited to the area of the first via hole 221.

Moreover, the maximum width of the first via hole 221 in the LED device 200 in the central region 11 is greater than the maximum width of the first via hole 221 in the LED device 200 in the annular region 12.

Thus, for LED devices 200 near the edge of the substrate 10, the area of the contact surface between the first via hole 221 and the epitaxial layer 210 is relatively small, while for LED devices 200 near the center of the substrate 10, the area of the contact surface is relatively large. If a situation occurs where the thickness of the transparent conductive layer 230 evaporated in the central region 11 of the substrate is greater than that in the edge region of the substrate, the smaller contact area corresponding to the first via hole 221 of the LED device 200 at the edge of the substrate 10 reduces the light-emitting area of the LED device, thereby offsetting the luminous efficacy improvement due to the thinner transparent conductive layer 230. Similarly, the larger contact area corresponding to the first via hole 221 of the LED device 200 at the center of the substrate 10 increases the light-emitting area of the LED device, thereby mitigating the light absorption issue caused by the thicker transparent conductive layer 230. Therefore, this embodiment can improve the brightness uniformity of LEDs in different regions on the substrate.

In implementation, the evaporation apparatus for evaporating the transparent conductive layer 230 may be a Plasma Enhanced Chemical Vapor Deposition (PECVD) apparatus. The transparent conductive layer 230 is fabricated by magnetron sputtering. Due to fluctuations in the PECVD apparatus, the thickness of the transparent conductive layer 230 formed on the substrate 10 may be uneven, and the thicknesses of the transparent conductive layers 230 in the LED devices 200 in the central region 11 at the center of the substrate 10 are greater than the thicknesses of the transparent conductive layers 230 in the LED devices 200 in the annular region 12 at the edge of the substrate 10.

Optionally, as shown in FIG. 1, the substrate 10 is a wafer, the central region 11 is circular, the annular region 12 is annular, and the annular region 12 and the central region 11 are concentrically distributed.

In this embodiment, the substrate 10 is a 4-inch wafer with a radius of 50000 µm. This embodiment does not limit the size of the substrate 10, which can be any size where uneven thickness of the transparent conductive layer 230 exists.

Optionally, the substrate is a sapphire substrate, a silicon substrate, or a silicon carbide substrate. The substrate can be a planar substrate or a patterned substrate.

In some examples, the substrate is a sapphire substrate. The sapphire substrate has relatively high transmittance, i.e., the substrate is transparent. Moreover, sapphire material is relatively hard and chemically stable, providing good light-emitting performance and stability for the LED.

Optionally, the transparent conductive layer 230 may be an Indium Tin Oxide (ITO) layer. The ITO layer has good transmittance and low resistivity. Using an ITO layer as the transparent conductive layer 230 allows more light to transmit through, ensuring light output efficiency. Simultaneously, due to its low resistivity, it facilitates carrier conduction and improves injection efficiency.

Exemplarily, the transparent conductive layer 230 may be an Indium Zinc Oxide (IZO) layer. An IZO layer has good transmittance and low resistivity. Using an IZO layer as the transparent conductive layer 230 allows more light to transmit through, ensuring light output efficiency. Simultaneously, due to its low resistivity, it facilitates carrier conduction and improves injection efficiency.

Exemplarily, the thickness of the transparent conductive layer 230 may be 600 Å to 2000 Å. For example, the thickness of the transparent conductive layer is 1500 Å.

Exemplarily, a ratio of the radius of the central region 11 to the radius of the substrate 10 is 0.8 to 0.9.

When the evaporation apparatus forms the transparent conductive layer 230, the thickness of the film is consistent over the vast majority of the central portion of the substrate 10. Therefore, the ratio of the radius of the central region 11 to the radius of the substrate 10 is determined based on the film thickness of the transparent conductive layer 230 in each LED device. This ensures that transparent conductive layers 230 of the same thickness can connect to the epitaxial layer 210 through first via holes 221 of the same size, improving LED brightness uniformity.

For example, the ratio of the radius of the central region 11 to the radius of the substrate 10 is 0.85, and the thickness of the transparent conductive layer 230 within the central region 11 on the substrate 10 is 900 Å.

Optionally, the maximum width of the first via hole 221 of the LED device 200 in the central region 11 is 9 µm to 11 µm. Exemplarily, the maximum width of the first via hole 221 of the LED device 200 in the central region 11 may be 10 µm.

When the thickness of the transparent conductive layer 230 is 900 Å, limiting the maximum width of the first via hole 221 of the LED device 200 in the central region 11 within the above range can increase the light-emitting area of the LED device 200 in the central region 11, enhancing brightness to make the brightness of LED devices 200 in various regions on the substrate 10 tend to be consistent.

Exemplarily, a ratio of the width of the annular region 12 to the radius of the substrate 10 is 0.1 to 0.2. That is, the area other than the central region 11 is defined as the annular region 12. For example, the ratio of the width of the annular region 12 to the radius of the substrate 10 is 0.15.

When the evaporation apparatus forms the transparent conductive layer 230, the thickness of the film at the edge of the substrate 10 is smaller than that in the central region 11. Therefore, the transparent conductive layer 230 within the annular region 12 is thinner and connects to the epitaxial layer 210 through smaller first via holes 221, thereby reducing the brightness of LEDs in the annular region 12 and making the brightness of LED devices at various regions on the substrate 10 tend to be consistent.

It should be noted that the number of LED devices 200 in FIG. 1 is merely schematic. In actual production, the number of LED devices 200 far exceeds that shown in the figure. Because the number of LED devices 200 shown in FIG. 1 is small, for ease of illustration, the circular central region 11 does not encompass all LED devices 220 with the largest first via holes 221. In practical application, the transparent conductive layer 230 in the circular central region 11 is thicker and can encompass all LED devices 220 with the largest first via holes 221.

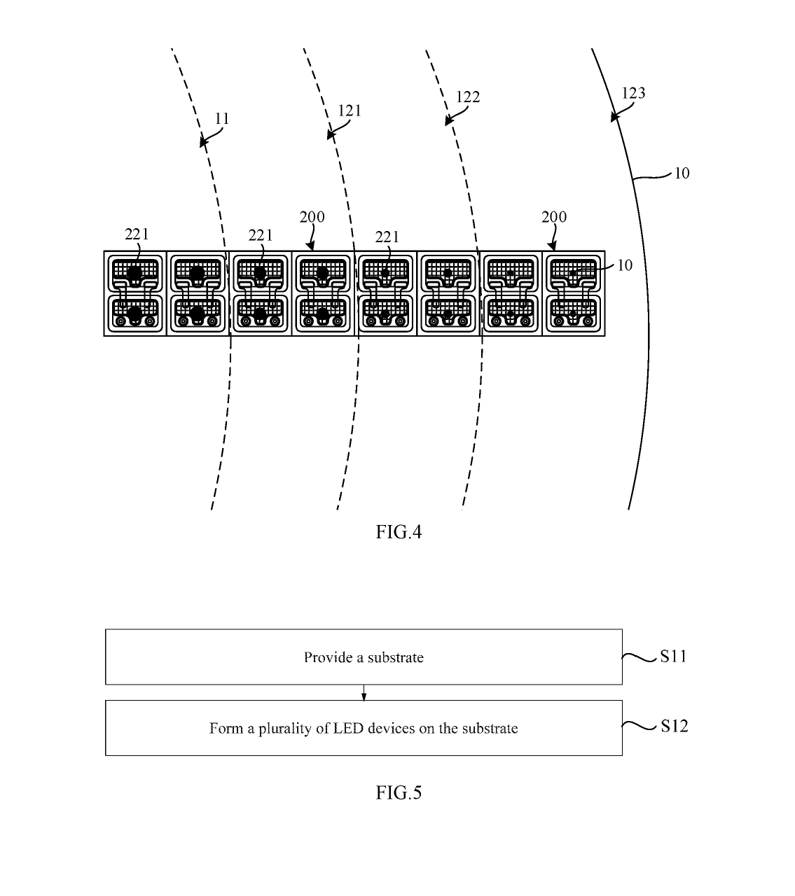

FIG. 4 is a partial enlarged view of area M in FIG. 1. As shown in FIG. 4, the annular region 12 includes a first sub-annular region 121, a second sub-annular region 122, and a third sub-annular region 123 sequentially surrounding the central region 11.

Exemplarily, a ratio of a width of the first sub-annular region 121 to the radius of the substrate 10 is 0.05 to 0.15. For example, the ratio of the width of the first sub-annular region 121 to the radius of the substrate 10 is 0.08.

In this embodiment, the thickness of the transparent conductive layer 230 within the first sub-annular region 121 is 860 Å.

Since the thickness of the transparent conductive layer 230 within the first sub-annular region 121 is smaller than that in the central region 11, the maximum width of the first via hole 221 in the first sub-annular region 121 can be smaller than the maximum width of the first via hole 221 in the central region 11 to balance the brightness of the LED devices 200 in the first sub-annular region 121 and the central region 11.

Optionally, the maximum width of the first via hole 221 of the LED device 200 in the first sub-annular region 121 is 6 µm to 8 µm. Exemplarily, the maximum width of the first via hole 221 of the LED device 200 in the first sub-annular region 121 is 7 µm.

When the thickness of the transparent conductive layer 230 within the first sub-annular region 121 is 860 Å, limiting the maximum width of the first via hole 221 of the LED device 200 in the first sub-annular region 121 within the above range, compared to the central region, reduces the maximum width of the first via hole 221 in the first sub-annular region 121, making the area of the first via hole through which the transparent conductive layer 230 injects current into the epitaxial layer smaller. This can reduce the brightness of the LED devices 200 in the first sub-annular region 121, making the brightness of LED devices 200 in various regions of the substrate 10 tend to be consistent.

Exemplarily, a ratio of a width of the second sub-annular region 122 to the radius of the substrate 10 is 0.05 to 0.1. For example, the ratio of the width of the second sub-annular region 122 to the radius of the substrate 10 is 0.05.

In this embodiment, the thickness of the transparent conductive layer 230 within the second sub-annular region 122 is 840 Å.

Since the thickness of the transparent conductive layer 230 within the second sub-annular region 122 is smaller than that within the first sub-annular region 121 and the central region 11, the maximum width of the first via hole 221 in the second sub-annular region 122 can be smaller than the maximum width of the first via hole 221 in the first sub-annular region 121 to balance the brightness of LED devices 200 in the two sub-regions.

Optionally, the maximum width of the first via hole 221 of the LED device 200 in the second sub-annular region 122 is 4 µm to 6 µm. Exemplarily, the maximum width of the first via hole 221 of the LED device 200 in the second sub-annular region 122 is 5.5 µm.

It should be noted that the maximum width of the first via hole 221 of the LED device 200 in the second sub-annular region 122 is smaller than the maximum width of the first via hole 221 of the LED device 200 in the first sub-annular region 121. When the maximum width of the first via hole 221 of the LED device 200 in the second sub-annular region 122 is 6 µm, the maximum width of the first via hole 221 of the LED device 200 in the first sub-annular region 121 needs to be greater than 6 µm.

When the thickness of the transparent conductive layer 230 within the second sub-annular region 122 is 840 Å, limiting the maximum width of the first via hole 221 of the LED devices 200 in the second sub-annular region 122 within the above range, compared to the first sub-annular region, further reduces the maximum width of the first via hole in the second sub-annular region, making the area of the first via hole through which the transparent conductive layer injects current into the epitaxial layer even smaller. This can reduce the brightness of the LED devices 200 in the second sub-annular region, making the brightness of LED devices 200 in various regions of the substrate 10 tend to be consistent.

Exemplarily, a ratio of a width of the third sub-annular region 123 to the radius of the substrate 10 is 0.02 to 0.05. For example, the ratio of the width of the third sub-annular region 123 to the radius of the substrate 10 is 0.02.

In this embodiment, the thickness of the transparent conductive layer 230 within the third sub-annular region 123 is 820 Å.

Since the thickness of the transparent conductive layer 230 within the third sub-annular region 123 is smaller than that within the second sub-annular region 122 and the central region 11, the maximum width of the first via hole 221 in the third sub-annular region 123 can be smaller than the maximum width of the first via hole 221 in the second sub-annular region 122 to balance the brightness of LED devices 200 in the two sub-regions.

Optionally, the maximum width of the first via hole 221 of the LED device 200 in the third sub-annular region 123 is 3 µm to 5 µm. Exemplarily, the maximum width of the first via hole 221 of the LED device 200 in the third sub-annular region 123 is 4 µm.

It should be noted that the maximum width of the first via hole 221 of the LED device 200 in the third sub-annular region 123 is smaller than the maximum width of the first via hole 221 of the LED device 200 in the second sub-annular region 122. When the maximum width of the first via hole 221 of the LED device 200 in the third sub-annular region 123 is 4 µm, the maximum width of the first via hole 221 of the LED device 200 in the second sub-annular region 122 needs to be greater than 4 µm. When the maximum width of the first via hole 221 of the LED device 200 in the third sub-annular region 123 is 5 µm, the maximum width of the first via hole 221 of the LED device 200 in the second sub-annular region 122 needs to be greater than 5 µm.

When the thickness of the transparent conductive layer 230 within the third sub-annular region 123 is 820 Å, limiting the maximum width of the first via hole 221 of the LED devices 200 in the third sub-annular region 123 within the above range, compared to the second sub-annular region 122, further reduces the maximum width of the first via hole in the third sub-annular region 123, making the area of the first via hole through which the transparent conductive layer injects current into the epitaxial layer even smaller. This can reduce the brightness of the LED devices 200 in the third sub-annular region, making the brightness of LED devices 200 in various regions of the substrate 10 tend to be consistent.

It should be noted that FIGS. 1 and 4 illustrate an example where the annular region 12 includes three sub-annular regions. In other embodiments, the annular region 12 may not be divided into sub-annular regions, or may include 2, 4, or more sub-annular regions. In this embodiment, the number and division positions of the annular regions can be determined based on the thickness of the transparent conductive layer 230 formed on the substrate, which is not limited herein.

When the number of sub-annular regions included in the annular region 12 is greater than 1, for any two adjacent sub-annular regions, the maximum width of the first via hole 221 of the LED device 200 in the sub-annular region proximal to the central region 11 is greater than the maximum width of the first via hole 221 of the LED device 200 in the sub-annular region distal from the central region 11, and the thickness of the transparent conductive layer 230 of the LED device 200 in the sub-annular region proximal to the central region 11 is greater than the thickness of the transparent conductive layer 230 of the LED device 200 in the sub-annular region distal from the central region 11. That is, the maximum width of the first via hole 221 of the LED device in each sub-annular region decreases along the direction away from the center of the substrate 10, and the thickness of the transparent conductive layer 230 of the LED device in each annular region decreases along the direction away from the center of the substrate 10.

As shown in FIG. 3, in one implementation, the epitaxial layer 210 of each LED device 200 includes a first light-emitting unit 211 and a second light-emitting unit 212 spaced apart. Each of the first light-emitting unit 211 and the second light-emitting unit 212 includes a first semiconductor layer 213, a multiple quantum well layer 214, and a second semiconductor layer 215 sequentially stacked. The second semiconductor layer 215 has a recess for exposing the first semiconductor layer 213. The first semiconductor layer 213 of the first light-emitting unit 211 is electrically connected to the second semiconductor layer 215 of the second light-emitting unit 212.

Exemplarily, one of the first semiconductor layer 213 and the second semiconductor layer 215 is a p-type layer, and the other is an n-type layer.

Exemplarily, the first semiconductor layer 213 is an n-type layer, and the second semiconductor layer 215 is a p-type layer.

Exemplarily, the first semiconductor layer 213 is a silicon-doped n-type GaN layer. A thickness of the n-type GaN layer may be 0.5 µm to 3 µm. As shown in FIG. 3, the recess exposes the n-type GaN layer.

Exemplarily, the multiple quantum well layer 214 includes alternately grown InGaN quantum well layers and GaN quantum barrier layers. The multiple quantum well layer 214 may include 3 to 8 periods of alternately stacked InGaN quantum well layers and GaN quantum barrier layers.

As an example, in this embodiment, the multiple quantum well layer 214 includes 5 periods of alternately stacked InGaN quantum well layers and GaN quantum barrier layers.

Exemplarily, a thickness of the multiple quantum well layer 214 may be 150 nm to 200 nm.

Exemplarily, the second semiconductor layer 215 is a magnesium-doped p-type GaN layer. A thickness of the p-type GaN layer may be 0.5 µm to 3 µm.

In this embodiment, current is transmitted to the transparent conductive layer, and then the current on the transparent conductive layer enters the epitaxial layer downward through the first via hole in the insulating layer, causing the epitaxial layer to emit light.

Since the transparent conductive layer can only contact the underlying second semiconductor layer through the first via hole, other areas of the second semiconductor layer are in direct contact with the insulating layer without the current spreading and ohmic contact of the transparent conductive layer. The second semiconductor layer in this area hardly emits light. Therefore, the area of the epitaxial layer corresponding to the first via hole is the light-emitting area of the epitaxial layer, and the area defined by the first via hole is the light-emitting area of the epitaxial layer.

As shown in FIG. 3, the insulating layer 220 covers the first light-emitting unit 211 and the second light-emitting unit 212 and is located on the surface of the substrate 10. The insulating layer 220 has first via holes 221 respectively exposing the two second semiconductor layers 215, and second via holes 222 respectively exposing the recesses of the first light-emitting unit 211 and the second light-emitting unit 212. The transparent conductive layer 230 is located on the two second semiconductor layers 215 and is connected to the two second semiconductor layers 215 through the two first via holes 221, respectively.

In the above implementation, each epitaxial layer 210 includes two light-emitting units arranged side by side. Each light-emitting unit includes a first semiconductor layer 213, a multiple quantum well layer 214, and a second semiconductor layer 215 sequentially stacked. The insulating layer 220 of both light-emitting units is provided with first via holes 221 exposing the second semiconductor layer 215, and the transparent conductive layers 230 of both light-emitting units are connected to the second semiconductor layer 215 through the first via holes 221. Moreover, the first semiconductor layer 213 of the first light-emitting unit 211 is electrically connected to the second semiconductor layer 215 of the second light-emitting unit 212, thereby connecting the first light-emitting unit 211 and the second light-emitting unit 212 in series. By applying electricity to the second semiconductor layer 215 of the first light-emitting unit 211 and the first semiconductor layer 213 of the second light-emitting unit 212, the two light-emitting units can be controlled to emit light simultaneously, enhancing the light-emitting effect of the epitaxial layer 210. Such an LED device with multiple light-emitting units connected in series can be referred to as a high-voltage LED device.

In related technologies, for high-voltage LED devices, reducing the light-emitting area is often used to improve light emission uniformity. For example, while keeping the LED chip size unchanged, the area of the transparent conductive layer is reduced. Since the primary electrode (e.g., the first electrode 31 described below) needs to be connected to the second semiconductor layer through the transparent conductive layer, if the area of the transparent conductive layer is too small, the primary electrode will cover the entire transparent conductive layer, and the light absorption by the primary electrode will significantly affect the luminous efficacy of the LED chip. Moreover, if the area of the transparent conductive layer is smaller than that of the primary electrode, part of the primary electrode will be in direct contact with the second semiconductor layer, resulting in poor ohmic contact, which is not conducive to current spreading and easily causes reliability issues.

In this embodiment, the area defined by the first via hole 221 in the insulating layer 220 is the light-emitting area of the epitaxial layer, and it is unnecessary to reduce the area of the transparent conductive layer 230 to reduce the light-emitting area, which is beneficial for improving the light emission uniformity of the LED device. Moreover, since there is no need to reduce the area of the transparent conductive layer 230, the transparent conductive layer 230 can completely separate the primary electrode from the second semiconductor layer, avoiding poor ohmic contact issues.

Optionally, the insulating layer 220 may have a single-layer structure or a multi-layer structure. The single-layer structure is a silicon oxide layer, a silicon nitride layer, an aluminum oxide layer, etc. The multi-layer structure may be formed by stacking at least two of a silicon oxide layer, a silicon nitride layer, and an aluminum oxide layer.

In some examples, the insulating layer 220 includes an aluminum oxide layer and a silicon oxide layer sequentially stacked. Since the etching rate of the aluminum oxide layer is lower than that of the silicon oxide layer, the opening formed by etching in the aluminum oxide layer is smaller, while the opening formed by etching in the silicon oxide layer is larger. Thus, after the aluminum oxide layer and the silicon oxide layer are stacked, the two openings can combine to form a via hole with inclined sidewalls.

Optionally, a thickness of the silicon oxide layer is greater than that of the aluminum oxide layer. This allows the sidewall of the first via hole to form a smaller angle with the surface of the insulating layer away from the substrate, facilitating subsequent coverage by the transparent conductive layer and providing better conformity.

Exemplarily, the thickness of the aluminum oxide layer is 600 Å to 1200 Å. For example, the thickness of the aluminum oxide layer is 1000 Å. The thickness of the silicon oxide layer is 2400 Å to 5000 Å. For example, the thickness of the silicon oxide layer is 3000 Å.

In this embodiment, as shown in FIG. 3, the first via hole 221 is a tapered hole, and a larger end of the first via hole 221 is away from the substrate 10. The cross-section of the first via hole 221 parallel to the substrate 10 is circular. In other embodiments, the cross-section of the first via hole 221 parallel to the substrate 10 may also be other shapes, such as rectangular and so on.

Optionally, an angle between the sidewall of the first via hole 221 and the surface of the insulating layer 220 away from the substrate 10 is 10° to 60°. Exemplarily, the angle between the sidewall of the first via hole 221 and the surface of the insulating layer 220 away from the substrate 10 is 30°.

In other embodiments, the first via hole 221 is a columnar hole.

Exemplarily, as shown in FIG. 3, each LED device 200 further includes a connection electrode 30. The connection electrode 30 is located on the insulating layer 220. A first portion of the connection electrode 30 is connected to the first semiconductor layer 213 of the first light-emitting unit 211 through the second via hole 222, and a second portion of the connection electrode 30 is connected to the transparent conductive layer 230 of the second light-emitting unit 212.

The connection electrode 30 can connect to the first semiconductor layer 213 of the first light-emitting unit 211 and the transparent conductive layer 230 of the second light-emitting unit 212, respectively, thereby achieving series connection of the first light-emitting unit 211 and the second light-emitting unit 212.

Exemplarily, as shown in FIGS. 2 and 3, the connection electrode 30 has an elongated structure. One end of the elongated structure is connected to the first semiconductor layer 213 of the first light-emitting unit 211 through the second via hole 222, the other end is connected to the transparent conductive layer 230 of the second light-emitting unit 212, and the middle portion of the elongated structure is located on the insulating layer 220 between the first light-emitting unit 211 and the second light-emitting unit 212.

In another implementation, the epitaxial layer of each LED device includes a first semiconductor layer, a multiple quantum well layer, and a second semiconductor layer sequentially stacked. The second semiconductor layer has a recess for exposing the first semiconductor layer. That is, each LED device includes only one light-emitting unit.

The insulating layer covers the epitaxial layer and is located on the surface of the substrate. The insulating layer has the first via hole exposing the second semiconductor layer and the second via hole exposing the recess. The transparent conductive layer is located on the second semiconductor layer and is connected to the second semiconductor layer through the first via hole.

Details regarding the first semiconductor layer, second semiconductor layer, and multiple quantum well layer can be referred to in the previous implementation and are omitted here.

Optionally, as shown in FIG. 3, each LED device 200 further includes a first electrode 31 and a second electrode 32. The first electrode 31 is located on the transparent conductive layer 230 of the first light-emitting unit 211. The second electrode 32 is located in the recess of the second light-emitting unit 212 and is connected to the first semiconductor layer 213 through the second via hole 222.

When the first semiconductor layer 213 is an n-type layer and the second semiconductor layer 215 is a p-type layer, the first electrode 31 is a p-electrode, and the second electrode 32 is an n-electrode. The first electrode 31 is located on the first light-emitting unit 211 and connected to the transparent conductive layer 230. The second electrode 32 is located in the recess and connected to the n-type layer exposed by the recess. Thus, applying electricity to the first electrode 31 and the second electrode 32 can control the two light-emitting units to emit light, improving the luminous efficacy of the LED device 200.

Optionally, as shown in FIG. 3, the LED device 200 further includes a passivation layer 40, a first bonding pad 51, and a second bonding pad 52. The passivation layer 40 is located on the insulating layer 220 and in the recesses, covering the first electrode 31 and the second electrode 32. The passivation layer 40 has a first through hole exposing the first electrode 31 and a second through hole exposing the second electrode 32. The first bonding pad 51 and the second bonding pad 52 are both located on the surface of the passivation layer 40 away from the substrate 10. The first bonding pad 51 is connected to the first electrode 31 through the first through hole, and the second bonding pad 52 is connected to the second electrode 32 through the second through hole.

Exemplarily, the passivation layer 40 has two first through holes exposing the first electrode 31 and two second through holes exposing the second electrode 32, so that the bonding pads provided on the surface of the passivation layer 40 away from the substrate 10 can connect to the two electrodes (i.e., the first electrode 31 and the second electrode 32) respectively, allowing an external power supply to supply power to the two electrodes through the through holes.

Exemplarily, the passivation layer 40 may be a Distributed Bragg Reflection (DBR) layer. The DBR layer includes multiple periodically alternating stacked SiO₂ layers and TiO₂ layers. The number of periods of the DBR layer may be between 20 and 50. For example, the number of periods is 32.

A thickness of the SiO₂ layer in the DBR layer may be 800 Å to 1200 Å, and a thickness of the TiO₂ layer in the DBR layer may be 500 Å to 900 Å.

In addition to the passivation function, the DBR layer can also reflect light from the multiple quantum well layer 214 towards the substrate 10, improving light output efficiency.

Optionally, the first bonding pad 51 and the second bonding pad 52 are both metal structures, which may be single-layer metal structures or multi-layer metal structures stacked sequentially.

Exemplarily, each of the first bonding pad 51 and the second bonding pad 52 may include a first Al layer, a first Ti layer, a second Al layer, a second Ti layer, and an Au layer sequentially stacked.

A thickness of the first Al layer is 8000 Å to 12000 Å, a thickness of the first Ti layer is 100 Å to 500 Å, a thickness of the second Al layer is 8000 Å to 12000 Å, a thickness of the second Ti layer is 500 Å to 1500 Å, and a thickness of the Au layer is 2000 Å to 5000 Å.

For example, the thickness of the first Al layer is 10000 Å, the thickness of the first Ti layer is 200 Å, the thickness of the second Al layer is 10000 Å, the thickness of the second Ti layer is 1000 Å, and the thickness of the Au layer is 3000 Å.

In this embodiment, the bonding pad may also be referred to as a pad electrode.

Optionally, as shown in FIG. 2, the transparent conductive layer 230 includes two conductive portions 230a. Each conductive portion 230a has a rectangular region 231 and a protruding region 232 connected thereto. The protruding region 232 is located at a long side of the rectangular region 231. One conductive portion 230a is located on the second semiconductor layer 215 of the first light-emitting unit 211, and the other conductive portion 230a is located on the second semiconductor layer 215 of the second light-emitting unit 212.

Each of the first light-emitting unit 211 and the second light-emitting unit 212 has two recesses X. In the first light-emitting unit 211, the two recesses X are located on two sides of the protruding region 232 corresponding to the first light-emitting unit 211. In the second light-emitting unit 212, the two recesses X are located on two sides of the protruding region 232 corresponding to the second light-emitting unit 212.

By designing the transparent conductive layer to include two conductive portions, each including a rectangular region and a protruding region, the conductive portion takes a T-shape (or convex shape). This allows the transparent conductive layer to cover a larger area of the second semiconductor layer, facilitating flexible arrangement of the relative positions between bonding pads and electrodes. Moreover, providing recesses on both sides of the protruding region facilitates electrical connection between the first and second light-emitting units, and between the second light-emitting unit and the second bonding pad.

Exemplarily, as shown in FIG. 2, the first light-emitting unit 211 and the second light-emitting unit 212 are connected in series through two connection electrodes 30. One connection electrode 30 is respectively provided in each of the two recesses of the first light-emitting unit 211, which can improve the connection reliability between the two light-emitting units. Meanwhile, the second bonding pad 52 can also connect to the first semiconductor layer 213 through the second electrodes 32 in the two recesses to stably transmit current to the first semiconductor layer of the epitaxial layer.

Exemplarily, the two connection electrodes 30 are symmetrically arranged. As shown in FIG. 2, the width of the portion of each connection electrode 30 located in the recess is greater than the width of the portion connected to the transparent conductive layer 230 of the second light-emitting unit 212. That is, in FIG. 2, the width of the upper end of the connection electrode 30 is greater than the width of its lower end, thereby improving the reliability of the connection between the connection electrode 30 and the first semiconductor layer 213 of the first light-emitting unit 211. Here, the width refers to the dimension of the connection electrode 30 in the direction perpendicular to the arrangement direction of the first light-emitting unit 211 and the second light-emitting unit 212.

Optionally, as shown in FIG. 2, a center of the first via hole 221 is positioned on a midline of the long side of the rectangular region 231 and on a midline of a perpendicular line between a side of the protruding region 232 away from the rectangular region 231 and a long side of the rectangular region 231 away from the protruding region 232.

The first via hole is positioned at the geometric center of the T-shaped transparent conductive layer, so that the light-emitting region of the light-emitting unit is located at the center of the light-emitting unit, ensuring the light-emitting effect.

Optionally, as shown in FIG. 2, the first light-emitting unit 211 has two first electrodes 31 symmetrically distributed on the transparent conductive layer 230. The second light-emitting unit 212 has two second electrodes 32 respectively located in the two recesses of the second light-emitting unit 212 and symmetrically distributed. The two first electrodes 31 and the two second electrodes 32 are symmetrically distributed.

In the above implementation, the four electrodes (i.e., the two first electrodes 31 and the two second electrodes 32) are distributed at four corners of the LED device and are mutually symmetrical. This allows current to be injected from the edges of the LED device, while the first via hole of each light-emitting unit is set at the center of the light-emitting unit. Therefore, current spreads from the edges of the LED device towards the center, facilitating lateral current spreading and improving current injection efficiency.

Exemplarily, the orthographic projection of the first electrode 31 on the bearing surface of the substrate 10 falls within the orthographic projection of the transparent conductive layer 230 on the bearing surface of the substrate 10, and the orthographic projection of the first electrode 31 on the bearing surface of the substrate 10 does not overlap with the orthographic projection of the first via hole 221 on the bearing surface of the substrate 10. This can prevent the first electrode 31 from absorbing light and affecting the luminous efficiency of the LED device.

FIG. 5 is a flowchart of a preparation method of an article according to an embodiment of the present disclosure. This method is used to prepare the LED shown in FIG. 2. As shown in FIG. 5, the preparation method includes:

S11: Provide a substrate.

Optionally, the substrate is a sapphire substrate, a silicon substrate, or a silicon carbide substrate. The substrate can be a planar substrate or a patterned substrate.

As an example, the substrate is a sapphire substrate. The sapphire substrate is a commonly used substrate with mature technology and low cost. The sapphire substrate can be a patterned sapphire substrate or a planar sapphire substrate.

Optionally, before S12, the sapphire substrate may be pre-treated by placing it in a Metal-organic Chemical Vapor Deposition (MOCVD) reaction chamber and baking it for 12 minutes to 18 minutes. As an example, in this embodiment, the sapphire substrate is baked for 15 minutes.

Specifically, a baking temperature may be 1000°C to 1200°C, and a pressure in the MOCVD reaction chamber during baking may be 100 mbar to 200 mbar.

S12: Form a plurality of LED devices on the substrate.

Each LED device includes an epitaxial layer, an insulating layer, and a transparent conductive layer sequentially stacked on the substrate. The insulating layer has a first via hole exposing the epitaxial layer, and the transparent conductive layer is connected to the epitaxial layer through the first via hole.

In this embodiment, the substrate has a central region and an annular region surrounding the central region. A plurality of LED devices are arranged in both the central region and the annular region. An area of a contact surface between the first via hole and the epitaxial layer in the LED device in the central region is greater than an area of a contact surface between the first via hole and the epitaxial layer in the LED device in the annular region, and a thickness of the transparent conductive layer in the LED device in the central region is greater than a thickness of the transparent conductive layer in the LED device in the annular region.

S12, forming the LED devices, may include the following steps:

Step one: Form a first light-emitting unit and a second light-emitting unit spaced apart on the substrate.

Each of the first light-emitting unit and the second light-emitting unit includes a first semiconductor layer, a multiple quantum well layer, and a second semiconductor layer sequentially stacked. The second semiconductor layer has a recess for exposing the first semiconductor layer.

Optionally, in this step, the first semiconductor layer, the multiple quantum well layer, and the second semiconductor layer are sequentially formed on the sapphire substrate using MOCVD technology; and patterning processes are performed on each film layer to form the first light-emitting unit and the second light-emitting unit.

Exemplarily, the first semiconductor layer is an n-type GaN layer. The growth temperature for the n-type GaN layer may be 1000°C to 1100°C, and the growth pressure may be 100 torr to 300 torr.

Optionally, the multiple quantum well layer includes alternately grown InGaN quantum well layers and GaN quantum barrier layers. When growing the multiple quantum well layer, the pressure in the MOCVD reaction chamber is controlled at 200 torr. When growing the InGaN quantum well layer, the reaction chamber temperature is 760°C to 780°C. When growing the GaN quantum barrier layer, the reaction chamber temperature is 860°C to 890°C.

Exemplarily, the second semiconductor layer is a p-type GaN layer. When growing the p-type GaN layer, the growth pressure may be 200 Torr to 600 Torr, and the growth temperature may be 800°C to 1000°C.

Exemplarily, performing patterning processes on each film layer to form the first light-emitting unit and the second light-emitting unit includes: etching the LED device region to form recesses in the second semiconductor layer from the surface thereof away from the substrate.

The recesses may be formed by dry etching or by photolithography combined with wet etching, such as using a mixed solution of H₃PO₄/H₂SO₄.

Step two: Fabricate an insulating layer on the surface of the substrate, the first light-emitting unit, and the second light-emitting unit.

The insulating layer has first via holes respectively exposing the two second semiconductor layers, and second via holes respectively exposing the recesses of the first light-emitting unit and the second light-emitting unit.

In this embodiment, the insulating layer includes an aluminum oxide layer and a silicon oxide layer sequentially stacked.

Optionally, forming the insulating layer may include: forming an aluminum oxide layer on the surfaces of the substrate, the first light-emitting unit, and the second light-emitting unit; forming a silicon oxide layer on the surface of the aluminum oxide layer; and forming via holes in the insulating layer by etching.

Since the etching rate of the aluminum oxide layer is lower than that of the silicon oxide layer, the opening formed by etching in the aluminum oxide layer is smaller, while the opening formed in the silicon oxide layer is larger. Thus, after the aluminum oxide layer and the silicon oxide layer are stacked, the two openings combine to form a via hole with inclined sidewalls.

A thickness of the silicon oxide layer is greater than that of the aluminum oxide layer, allowing the sidewall of the first via hole to form a smaller angle with the surface of the insulating layer away from the substrate, facilitating subsequent coverage by the transparent conductive layer and providing better conformity.

Step three: Form a transparent conductive layer on the insulating layer. The transparent conductive layer is located on the two second semiconductor layers and is connected to the two second semiconductor layers through the two first via holes, respectively.

After forming the insulating layer, the preparation method further includes forming a transparent conductive layer on the surface of the insulating layer. The transparent conductive layer extends through the first via holes to the surfaces of the second semiconductor layers of the two light-emitting units.

After step S12, the method further includes: fabricating a first electrode on the surface of the transparent conductive layer of the first light-emitting unit, and fabricating a second electrode in the recess of the second light-emitting unit.

The first electrode is primarily composed of AuBe, and the second electrode is formed by evaporating AuGe as the base material. When evaporating the AuGe alloy, the evaporation power should be ensured to avoid evaporation time exceeding a certain number of seconds to prevent deviation in alloy composition, followed by annealing.

Optionally, after fabricating the first and second electrodes, the preparation method further includes: forming a passivation layer on the surfaces of the insulating layer, the transparent conductive layer, the first electrode, and the second electrode; after forming the passivation layer, etching first through holes and second through holes in the surface of the passivation layer. The first through holes expose the first electrode, and the second through holes expose the second electrode.

After etching the first and second through holes in the passivation layer, the preparation method further includes: fabricating a first bonding pad and a second bonding pad on the surface of the passivation layer.

The first bonding pad is connected to the first electrode through the first through hole, and the second bonding pad is connected to the second electrode through the second through hole.

In this embodiment, the preparation method may further include: forming a protective layer on the surface of the passivation layer.

Exemplarily, in this embodiment, the protective layer may be a silicon oxide layer with a thickness of 2000 Å.

Finally, the sapphire substrate may undergo stealth dicing and breaking. Stealth dicing can better reduce brightness loss. Then, testing yields the LED.

There is also provided an LED in an embodiment of the present disclosure, which includes the aforementioned LED device. Optionally, the LED further includes a substrate, and the LED device is located on the substrate.

The above descriptions are merely optional embodiments of the present disclosure and are not intended to limit the present disclosure. Any modifications, equivalent replacements, improvements, etc., made within the spirit and principles of the present disclosure shall be included within the scope of protection of the present disclosure.

What is claimed is:

1. A light emitting diode, comprising:
a substrate, a first light-emitting unit, a second light-emitting unit, an insulating layer, and a transparent conductive layer, the first light-emitting unit and the second light-emitting unit being spaced apart and each comprising a first semiconductor layer, a multiple quantum well layer, and a second semiconductor layer sequentially stacked, the second semiconductor layer having a recess for exposing the first semiconductor layer;
the insulating layer covering the first light-emitting unit and the second light-emitting unit and being disposed on a surface of the substrate, the insulating layer having two first via holes respectively exposing two second semiconductor layers, and two second via holes respectively exposing two recesses;
the transparent conductive layer being disposed on the two second semiconductor layers and respectively connected to the two second semiconductor layers through the two first via holes; and
the first semiconductor layer of the first light-emitting unit being electrically connected to the second semiconductor layer of the second light-emitting unit.

2. The light emitting diode according to claim 1, wherein
the light emitting diode further comprises a connection electrode, a first electrode, and a second electrode;
the connection electrode is disposed on the insulating layer; a first portion of the connection electrode is connected to the first semiconductor layer of the first light-emitting unit through the second via hole, and a second portion of the connection electrode is connected to the transparent conductive layer of the second light-emitting unit; and
the first electrode is disposed on the transparent conductive layer of the first light-emitting unit, and the second electrode is disposed in the recess of the second light-emitting unit and connected to the first semiconductor layer through the second via hole.

3. The light emitting diode according to claim 1, wherein
the transparent conductive layer comprises two conductive portions, each conductive portion having a rectangular region and a protruding region connected thereto; the protruding region is disposed at a long side of the rectangular region, one of the two conductive portions is disposed on the second semiconductor layer of the first light-emitting unit, and the other of the two conductive portions is disposed on the second semiconductor layer of the second light-emitting unit; and
each of the first light-emitting unit and the second light-emitting unit has two recesses; the two recesses of the first light-emitting unit are disposed on two sides of the protruding region corresponding to the first light-emitting unit, and the two recesses of the second light-emitting unit are disposed on two sides of the protruding region corresponding to the second light-emitting unit.

4. The light emitting diode according to claim 3, wherein
a center of the first via hole is positioned on a midline of the long side of the rectangular region and on a midline of a perpendicular line between a side of the protruding region away from the rectangular region and a long side of the rectangular region away from the protruding region.

5. The light emitting diode according to claim 2, wherein
the first light-emitting unit has two first electrodes symmetrically distributed on the transparent conductive layer;
the second light-emitting unit has two second electrodes respectively disposed in the two recesses of the second light-emitting unit and symmetrically arranged; and
the two first electrodes and the two second electrodes are symmetrically distributed.

6. The light emitting diode according to claim 2, wherein the light emitting diode comprises two connection electrodes which are symmetrically arranged.

7. The light emitting diode according to claim 1, wherein the insulating layer comprises an aluminum oxide layer and a silicon oxide layer sequentially stacked.

8. An article, comprising:
a substrate and a plurality of light emitting diode devices disposed on the substrate, each light emitting diode device comprising an epitaxial layer, an insulating layer, and a transparent conductive layer sequentially stacked on the substrate, the insulating layer having a first via hole exposing the epitaxial layer, the transparent conductive layer being connected to the epitaxial layer through the first via hole;
the substrate having a central region and an annular region surrounding the central region, a plurality of the light emitting diode devices being arranged in both the central region and the annular region; and
an area of a contact surface between the first via hole and the epitaxial layer in the light emitting diode device in the central region being greater than an area of a contact surface between the first via hole and the epitaxial layer in the light emitting diode device in the annular region, and a thickness of the transparent conductive layer in the light emitting diode device in the central region being greater than a thickness of the transparent conductive layer in the light emitting diode device in the annular region.

9. The article according to claim 8, wherein the substrate is a wafer, the central region is circular, the annular region is annular, and the central region and the annular region are concentrically distributed.

10. The article according to claim 9, wherein a ratio of a radius of the central region to a radius of the substrate is 0.8 to 0.9, and a ratio of a width of the annular region to the radius of the substrate is 0.1 to 0.2.

11. The article according to claim 9, wherein
the annular region comprises a plurality of sub-annular regions sequentially surrounding the central region;
for any two adjacent sub-annular regions among the plurality of sub-annular regions, a maximum width of the first via hole in the light emitting diode device in the sub-annular region proximal to the central region is greater than a maximum width of the first via hole in the light emitting diode device in the sub-annular region distal from the central region, and a thickness of the transparent conductive layer in the light emitting diode device in the sub-annular region proximal to the central region is greater than a thickness of the transparent conductive layer in the light emitting diode device in the sub-annular region distal from the central region.

12. The article according to claim 11, wherein
the annular region comprises a first sub-annular region, a second sub-annular region, and a third sub-annular region sequentially surrounding the central region; and
a ratio of a width of the first sub-annular region to the radius of the substrate is 0.05 to 0.15, a ratio of a width of the second sub-annular region to the radius of the substrate is 0.03 to 0.1, and a ratio of a width of the third sub-annular region to the radius of the substrate is 0.02 to 0.05.

13. The article according to claim 12, wherein the first via holes of the light emitting diode devices have the same shape; a maximum width of the first via hole of the light emitting diode device in the first sub-annular region is 6 µm to 8 µm; a maximum width of the first via hole of the light emitting diode device in the second sub-annular region is 4 µm to 6 µm; and a maximum width of the first via hole of the light emitting diode device in the third sub-annular region is 3 µm to 5 µm.

14. The article according to claim 8, wherein a maximum width of the first via hole of the light emitting diode device in the central region is 9 µm to 11 µm.

15. The article according to claim 8, wherein
the epitaxial layer comprises a first light-emitting unit and a second light-emitting unit, the first light-emitting unit and the second light-emitting unit each comprising a first semiconductor layer, a multiple quantum well layer, and a second semiconductor layer sequentially stacked, the second semiconductor layer having a recess for exposing the first semiconductor layer;
the insulating layer covers the first light-emitting unit and the second light-emitting unit and is disposed on a surface of the substrate; the insulating layer has first via holes exposing the second semiconductor layer of the first light-emitting unit and the second semiconductor layer of the second light-emitting unit, and second via holes exposing the recess of the first light-emitting unit and the recess of the second light-emitting unit;
the transparent conductive layer is disposed on two second semiconductor layers and respectively connected to the two second semiconductor layers through two first via holes; and
the first semiconductor layer of the first light-emitting unit is electrically connected to the second semiconductor layer of the second light-emitting unit.

16. The article according to claim 15, wherein
the light emitting diode device further comprises a connection electrode, a first electrode, and a second electrode;
the connection electrode is disposed on the insulating layer; a first portion of the connection electrode is connected to the first semiconductor layer of the first light-emitting unit through the second via hole, and a second portion of the connection electrode is connected to the transparent conductive layer of the second light-emitting unit; and
the first electrode is disposed on the transparent conductive layer of the first light-emitting unit, and the second electrode is disposed in the recess of the second light-emitting unit and connected to the first semiconductor layer through the second via hole.

17. The article according to claim 15, wherein
the transparent conductive layer comprises two conductive portions, each conductive portion having a rectangular region and a protruding region connected thereto, the protruding region being disposed at a long side of the rectangular region, one of the two conductive portions being disposed on the second semiconductor layer of the first light-emitting unit, the other of the two conductive portions being disposed on the second semiconductor layer of the second light-emitting unit; and
each of the first light-emitting unit and the second light-emitting unit has two recesses; the two recesses of the first light-emitting unit are disposed on two sides of the protruding region corresponding to the first light-emitting unit, and the two recesses of the second light-emitting unit are disposed on two sides of the protruding region corresponding to the second light-emitting unit.

18. The article according to claim 17, wherein a center of the first via hole is positioned on a midline of the long side of the rectangular region and on a midline of a perpendicular line between a side of the protruding region away from the rectangular region and a long side of the rectangular region away from the protruding region.

19. The article according to claim 16, wherein
the first light-emitting unit has two first electrodes symmetrically distributed on the transparent conductive layer;
the second light-emitting unit has two second electrodes respectively disposed in the two recesses of the second light-emitting unit and symmetrically arranged; and
the two first electrodes and the two second electrodes are symmetrically distributed.

20. A preparation method of an article, comprising:
providing a substrate having a central region and an annular region surrounding the central region; and
forming a plurality of light emitting diode devices on the substrate, each light emitting diode device comprising an epitaxial layer, an insulating layer, and a transparent conductive layer sequentially stacked on the substrate, the insulating layer having a first via hole exposing the epitaxial layer, the transparent conductive layer being connected to the epitaxial layer through the first via hole; wherein
a plurality of the light emitting diode devices are arranged in both the central region and the annular region, an area of a contact surface between the first via hole and the epitaxial layer in the light emitting diode device in the central region is greater than an area of a contact surface between the first via hole and the epitaxial layer in the light emitting diode device in the annular region, and a thickness of the transparent conductive layer in the light emitting diode device in the central region is greater than a thickness of the transparent conductive layer in the light emitting diode device in the annular region.
